(19) United States
(12) Patent Application Publication
(10) Pub. No.: US 2019/0249940 A1
(43) Pub. Date: Aug. 15, 2019

(54) HEAT DISSIPATION PLATE AND MANUFACTURING METHOD THEREOF

(71) Applicant: Shan-Teng QUE, Taoyuan City (TW)

(72) Inventor: Shan-Teng QUE, Taoyuan City (TW)

(21) Appl. No.: 15/893,586

(22) Filed: Feb. 10, 2018

(51) Int. Cl. F28F 21/04; F28F 21/02

(52) U.S. Cl. CPC F28F 21/04; H01L 23/3735; F28F 21/02

(57) ABSTRACT

The present disclosure is related to a heat dissipation plate and manufacturing method thereof. The heat dissipation plate includes a substrate, a ceramic powder layer and a graphene layer, and the substrate has a heat absorbing surface and a heat dissipation surface. The ceramic powder layer is stacked on the heat dissipation surface. The ceramic powder layer is formed of photothermal conversable ceramic powder and has a thickness smaller than 100 μm. The graphene layer is stacked between the heat dissipation surface and the ceramic layer or disposed on the heat absorbing surface. The ceramic powder layer is photothermal conversable, and heat can be rapidly and uniformly distributed throughout the entire heat dissipation surface via the graphene layer. Thereby, heat radiation efficiency of the ceramic powder layer is increased, and heat dissipation efficiency of the heat dissipation plate of the present disclosure is higher than conventional heat dissipation plates.

### BACKGROUND OF THE INVENTION

### Field of the Invention

The technical field is related to a heat dissipation plate, in particular, to a heat dissipation plate and a manufacturing method thereof.

### Description of Related Art

For stable operation of electronic elements, typically, heat sinks are attached onto the electronic elements in order to utilize the heat sink to dissipate the thermal energy generated by the electronic elements into the atmosphere via convection. In addition, traditional heat sinks are known to be made of materials of high thermal conductivity, such as copper and aluminum etc., in order to use the thermal conduction method of high thermal conductivity to effectively transfer the heat into the atmosphere via convection.

However, to achieve diverse functions and optimal performance of electronic products nowadays, the use of heat sinks made of metals of high thermal conductivity, such as copper and aluminum, is insufficient to satisfy the requirements of space saving, slim product and high cooling efficiency for the new generations of electronic elements.

In view of above, the inventor seeks to overcome the aforementioned drawbacks associated with the currently existing technology after years of research and development along with the utilization of academic theories, which is also the objective of the development of the present invention.

### SUMMARY OF THE INVENTION

An objective of the present invention is to provide a heat dissipation plate and a manufacturing method thereof. The present invention is able to utilize a ceramic powder layer having the capacity of converting thermal energy into light energy (photothermal conversion) and a graphene layer capable of rapidly and uniformly transfer the heat over the entire heat dissipation surface in order to increase the thermal radiation efficiency of the entire heat dissipation surface of the ceramic powder layer. Consequently, the heat dissipation plate of the present invention can be made to have a small size with relatively greater heat dissipation efficiency.

To achieve the aforementioned objective, the present invention provides a heat dissipation plate, comprising: a substrate having a heat dissipation surface and a heat absorbing surface; a ceramic powder layer stacked onto the heat dissipation surface, the ceramic powder layer formed by a ceramic powder having a far infrared radiation capability, and a thickness of the ceramic powder layer being smaller than 100 μm; and a graphene layer stacked between the heat dissipation surface and the ceramic powder surface or disposed onto the heat absorbing surface; the graphene layer formed by a graphene material.

To achieve the aforementioned objective, the present invention provides a manufacturing method for a heat dissipation plate, comprising the steps of: a) providing a substrate and a graphene layer; the substrate having a heat dissipation surface; and disposing the graphene layer onto the heat dissipation surface; b) providing a ceramic powder having a far infrared radiation capability in order to perform a surface modification operation on the ceramic powder; the surface modification operation being adopted to adjust a grain size, a crystal phase or an appearance of the ceramic powder in order to increase a fluidity of the ceramic powder; and c) using a spray method to dispose the ceramic powder onto the graphene layer in order to form a ceramic powder layer.

To achieve the aforementioned objective, the present invention provides a manufacturing method for a heat dissipation plate, comprising the steps of: (d) providing a ceramic powder having a far infrared radiation capability to perform a surface modification operation on the ceramic powder; the surface modification operation being adopted to adjust a grain size, a crystal phase or an appearance of the ceramic powder in order to increase a fluidity of the ceramic powder; (e) providing a substrate, the substrate having a heat dissipation surface and a heat absorbing surface; using a spray method to dispose the ceramic powder onto the heat dissipation surface in order to form a ceramic powder layer; and (f) providing a graphene layer, and disposing the graphene layer onto the heat absorbing surface.

The present invention is able to achieve the following technical effects. The ceramic powder layer is disposed onto the graphene layer via a spray method in order to form a ceramic powder layer. Since the spray process is able to yield a thin and uniform coating layer structure and since the spray method is a manufacturing process capable forming the minimum thermal resistance, along with the control of the thickness and crystallization level of the ceramic powder layer, by disposing the graphene layer onto the heat dissipation surface, the graphene layer can be firmly attached onto the substrate in order to achieve a heat dissipation plate with excellent heat dissipation efficiency.

### BRIEF DESCRIPTION OF DRAWING

FIG. 1 is a process flowchart of a manufacturing method for a heat dissipation plate of the present invention;

FIG. 2 is a perspective exploded view of the heat dissipation plate of the present invention;

FIG. 3 is a process flowchart of a manufacturing method for a heat dissipation plate according to another embodiment of the present invention; and

FIG. 4 is a perspective exploded view of the heat dissipation plate according to another embodiment of the present invention.

### DETAILED DESCRIPTION OF THE INVENTION

The following provides a detailed technical content of the present invention along with the accompanied drawings. However, the accompanied drawings are provided for reference and illustrative purpose only such that they shall not be used to limit the scope of the present invention.

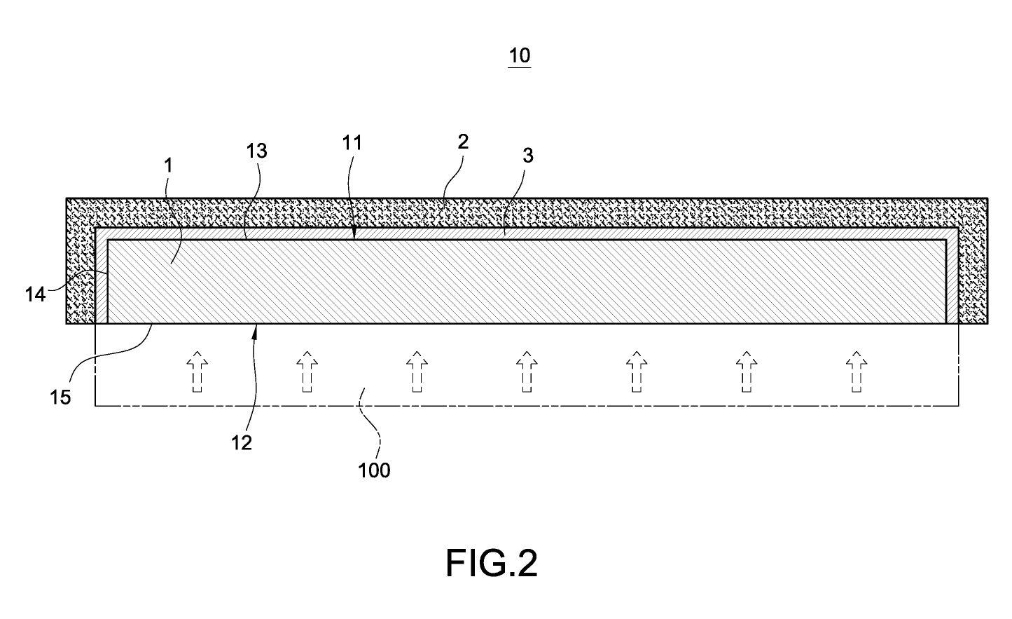

As shown in FIG and FIG. 2, the present invention provides a heat dissipation plate and a manufacturing process thereof. The following provides a detailed description on the steps thereof.

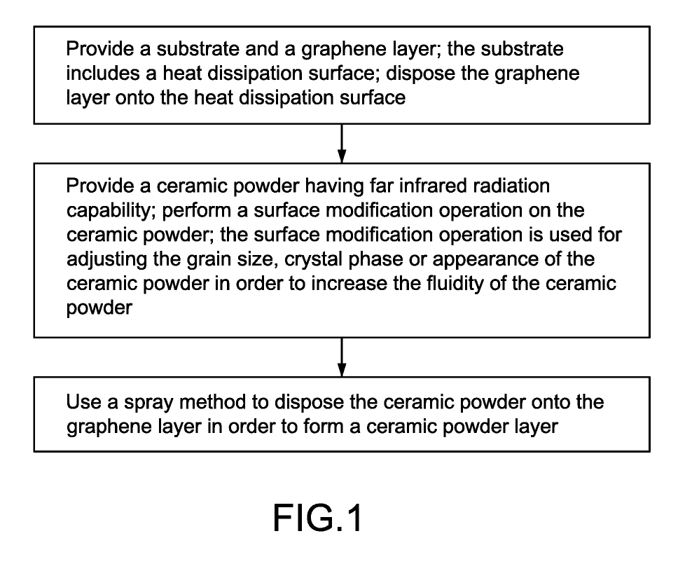

As shown in steps a)˜c) in FIG. 1 and FIG. 2, a substrate 1 and a graphene layer 3 are provided in step a). The substrate 1 includes a heat dissipation surface 1, and the graphene layer 3 can be disposed onto the heat dissipation surface via a spray method or a chemical vapor deposition method in order to allow the graphene layer to be firmly attached onto the substrate. In step b), a ceramic powder having a far infrared radiation capability is provided, and a surface modification operation is performed on the ceramic powder. The purpose of the surface modification operation is to adjust the grain size, crystal phase or appearance of the ceramic powder in order to increase the fluidity of the ceramic powder. In step c), the ceramic powder can be coated onto the graphene layer 3 via a cold spray or thermal spray method in order to form a ceramic powder layer 2.

Please refer to the following detailed description. The surface modification is also known as surface treatment or surface process, and its purpose to further adjust the physical or chemical properties of the ceramic powder surface. In the present invention, since the aforementioned ceramic powder having the far infrared radiation capability is coated and formed on the graphene layer 3, there is a need to perform surface modification operation on the ceramic powder in order to adjust the parameters of the grain size and appearance of the ceramic powder such that it can be more easily disposed onto the graphene layer 3 and is able to have greater bonding force. In addition, with such modification step, the crystal phase of the ceramic powder can also be adjusted. For example, through a heat treatment process, the crystal phase of the ceramic powder can be formed to become most advantageous to the subsequent manufacturing process or to achieve the effect of allowing the ceramic powder layer 2 to have greater heat dissipation efficiency. Moreover, such surface modification step can further include a deposition process in order to dispose a shell layer (not shown in the drawings) onto the surface of the ceramic powder layer, and the shell layer (not shown in the drawings can provide a greater fluidity (also known as lubricity) for the ceramic powder in order to facilitate the subsequent deposition step. For example, the method of electroplating, electroless deposition or chemical formation method etc. can be used to dispose a shell layer having a lower melting point. The shell layer of a lower melting point is able to allow the ceramic powder to be melted first during the deposition process and to form a fluid for filling the voids among the ceramic powders; therefore, the fluidity of the ceramic powder is increased and the characteristic of the ceramic powder layer 2 can be strengthened.

In addition, the aforementioned thermal spray (also known as the flame spray) technique refers to the method of heating the material to be disposed to a melting state with a heating source, and the disposing material can be of the form of wire, rod or powder, followed by using pressurized air to spray the melted or semi-melted material onto the surface of workpiece in order to form a deposition layer. In an exemplary embodiment of the present invention, the flame burning method can be used, such as the methods of flame spray, high velocity oxy-euel (HVOE) etc. or the use of electrical energy supply method, such as plasma spray, arc spray process etc. can be used in order to heat the far infrared material of ceramic powder to a melted or semi-melted state, followed by using high pressure airflow for atomizing and delivering the aforementioned melted or semi-melted particles onto the surface of the graphene layer 3. The ceramic powder particles of melted or semi-melted state impacts onto the surface of the graphene layer 3 with the high pressure airflow to form flat particles. After the plate ceramic powder particles are stacked layer by layer, it then undergoes the cooling step in order to form a ceramic layer 2 via spray formation.

Furthermore, the aforementioned cold spray method is a new spray technique. In such method, the ceramic powder is not melt or vaporized, but the ceramic powder is delivered along with an inert gas at ultrasonic flow velocity to impact the surface of the graphene layer 3 in order to form a ceramic powder layer 2. The powder material under the collisions at ultrasonic speed, the particles exceeding the threshold velocity can generate plastic deformation in order form a thin film. Such method is different form the conventionally known thermal spray method, and the material is not subject to heating to generate characteristic changes. In addition, the oxidation of the thin film can be controlled to a minimum level. Accordingly, the aforementioned spray method is able to continuously dispose the ceramic powder having the far infrared radiation capability onto the graphene layer in order to form the ceramic powder layer 2. Since the cold spray process is able to introduce cooling air, the temperature of the manufacturing process can be effectively reduced. Furthermore, since the cold spray implementation method has relatively fewer limitations on the dimension and sizes of the workpiece and since the film stacking speed of the cold spray is relatively fast, the thickness of the ceramic powder layer 2 is uniform. Therefore, the cold spray is quite suitable to a continuous spray operation performed automatically.

It shall be noted that despite that the far infrared material is able to absorb thermal energy into far infrared with greater radiation in order to use the radiation method to achieve the enhanced heat dissipation effect, nevertheless, the thermal conductivity of the ceramic powder layer 2 is lower than the substrate 1 such that the thickness of the substrate 1 must be within a certain range; otherwise, an excessive thickness of the film of the ceramic powder layer 2 can cause the thermal conductivity of the overall heat dissipation plate 10 to be reduced, which can lead to the result that although the radiation effect of heat is increased but the overall heat dissipation capacity may not be improved.

Furthermore, the substance of the far infrared is light ray, and the radiation effect can be achieved by disposing a thin layer only; therefore, the ceramic powder layer 2 on the heat dissipation plate 10 can be as thin as possible. In addition, since the mechanism of the radiation effect of the far infrared material originates from the crystal structure, a deposition layer having a thickness that is too thin cannot yield an excellent crystal structure, which can cause the far infrared emissivity to be reduced. Consequently, the ceramic powder layer 2 of the far infrared material shall have a lower limit thickness. In an exemplary embodiment, the ceramic powder layer 2 has a predefined uniform thickness, and such predefined thickness is small than 100 μm in order to prevent an overly thick deposition layer causing reduction of thermal conductivity. Moreover, under the condition where the thickness of the ceramic powder layer 2 is smaller than 100 μm, the crystal structure is able to achieve excellent far infrared radiation effect.

Please refer to FIG. 2. A heat dissipation plate 10 can be obtained based on the aforementioned manufacturing method, and such heat dissipation plate 10 mainly comprises a substrate 1, a ceramic powder layer 2 and a graphene layer 3.

The substrate 1 includes a heat dissipation surface 11 and a heat absorbing surface 12. The heat dissipation surface 11 can be formed on a top surface 13 and a lateral circumferential surface 14 of the substrate 1. The heat absorbing surface 12 can be formed on a bottom surface 15 of the substrate 1. In addition, the substrate 1 can be a plate workpiece made of a metal material of high thermal conductivity, such as aluminum or copper material.

The ceramic powder layer 2 is stacked onto the heat dissipation surface 11. The ceramic powder layer 2 is formed by a ceramic powder having a far infrared radiation capability, and a thickness of the ceramic powder layer is smaller than 100 μm. In addition, the infrared emissivity of the ceramic powder layer 2 is identical to the predefined infrared emissivity of the ceramic powder. Furthermore, the ceramic powder comprises clay, phyllite or tourmaline, and further description is provided in the following. The ceramic powder comprises potash feldspar, albite, vanadic titanomagnetite, copper oxide or DK2001.

Typically, far infrared materials are selected from ores, but their chemical compositions are complicated and cannot be controlled with ease. Most of such materials contain rare earth elements with radioactivity or heavy metal. The rare earth elements can stimulate the far infrared release of materials. There are a great number of inorganics with the far infrared function, and the powder colors are not the same. The materials of tourmaline, volcanic rock or heated phyllostachys edulis or coconut shell to a high temperature above 1000° C. also demonstrate to have the function of far infrared. As a result, for the present invention, there is a need to perform relevant analysis and experiment on the far infrared materials. In the present invention, the compositions of various types of far infrared materials are analyzed, and the crystal phases thereof are observed. Furthermore, based on the aforementioned analysis result, the ceramic powder of far infrared material is prepared such that the ceramic powder has a certain infrared emissivity. The predefined infrared emissivity is equivalent to the infrared emissivity of the far infrared material selected.

Moreover, according to an exemplary embodiment, the ceramic powder is made by a ceramic material having the far infrared radiation capability. For example, the ceramic material is made from a clay mixture, and it is formed by the clay of 10 to 15 percentage by weight, phyllite of 10 to 20 percentage by weight, tourmaline of 40 to 50 percentage by weight, potash feldspar of 5 to 10 percentage by weight, albite of 5 to 10 percentage by weight, vanadic titanomagnetite of 5 to 10 percentage by weight, copper oxide of 5 to 10 percentage by weight and organic DK2001 of 10 percentage by weight, which is formed via the processes of crushing, screening, mixing, stirring, graining, drying, sintering, crushing and blending. However, it shall be understood that the aforementioned composition ratio is provided as an example only, which shall not be used to limit the scope of the present invention. The ceramic powder formed based on the aforementioned composition elements can be used for disposing and attaching onto the heat dissipation surface 11 of the substrate 1.

The graphene layer 3 is stacked between the heat dissipation surface 11 and the ceramic powder layer 2 or is disposed onto the heat absorbing surface 12. The graphene layer 3 is formed by a graphene material. In addition, the graphene layer 3 is of high thermal conductivity, and the heat transfer efficiency of the graphene layer 3 is higher than the heat transfer efficiency of a metal material. Consequently, the graphene layer 3 is able to rapidly transfer the heat to the ceramic powder layer 2 in order increase the thermal radiation effect of the ceramic powder layer 2.

With regard to the assembly and usage states of the heat dissipation plate 10 of the present invention, it uses the substrate 1 having a heat dissipation surface 11 and a heat absorbing surface 12; the ceramic powder layer is stacked onto the heat dissipation surface 11, the ceramic powder layer 2 is formed by ceramic powder having the far infrared radiation capability, and the thickness of the ceramic powder layer 2 is smaller than 100 μm; and a graphene layer 3 is stacked between the heat dissipation surface 11 and the ceramic layer 2 or is disposed onto the heat absorbing layer 12, and the graphene layer 3 is formed by a graphene material. Accordingly, when the heat dissipation plate 10 is attached onto a heat generating unit 100 correspondingly, the heat from the heat generating unit is transferred outward by the substrate 1 with excellent thermal conductivity. Since the graphene layer 3 is of high thermal conductivity, the heat transfer efficiency of the graphene layer 3 is higher than the heat transfer efficiency of the metal material, and the graphene layer 3 is able to rapidly transfer the heat to the ceramic powder layer 2 in order to increase the thermal radiation effect of the ceramic powder layer 2. Furthermore, the ceramic powder layer 2 is an energy conversion carrier, and the thermal energy transferred from the substrate 1 to the ceramic powder layer 2 can generate electron transition due to the crystal structure with the far infrared radiation function such that the thermal energy is converted into a radiation type of energy form: the far infrared electromagnetic radiation is emitted outward, where its emission wavelength is 2˜18 μm, and the emissivity reaches 93%. In other words, the ceramic powder layer 2 is able to convert the thermal energy received into the form of light quantum not absorbing to metal materials for emission outward such that it can achieve the effect of fast heat dissipation; consequently, the cooling effect of the heat generating element 100 can be increased, and the useful lifetime of the heat generating unit 100 can be improved. Accordingly, the ceramic powder layer 2 is able to achieve the far infrared radiation effect and the graphene layer 3 has high thermal conductivity; therefore, the ceramic powder layer 2 has the photothermal conversion ability. As a result, the graphene layer 3 is able to rapidly and uniformly transfer the heat over the entire surface in order to increase the thermal emissivity of the entire surface of the ceramic powder layer 2 and to allow the heat dissipation plate 10 of the present invention to have an excellent heat dissipation efficiency.

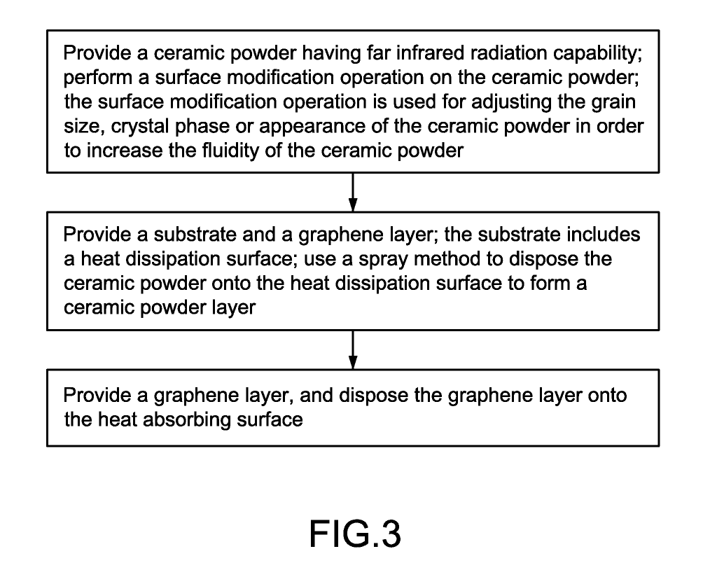

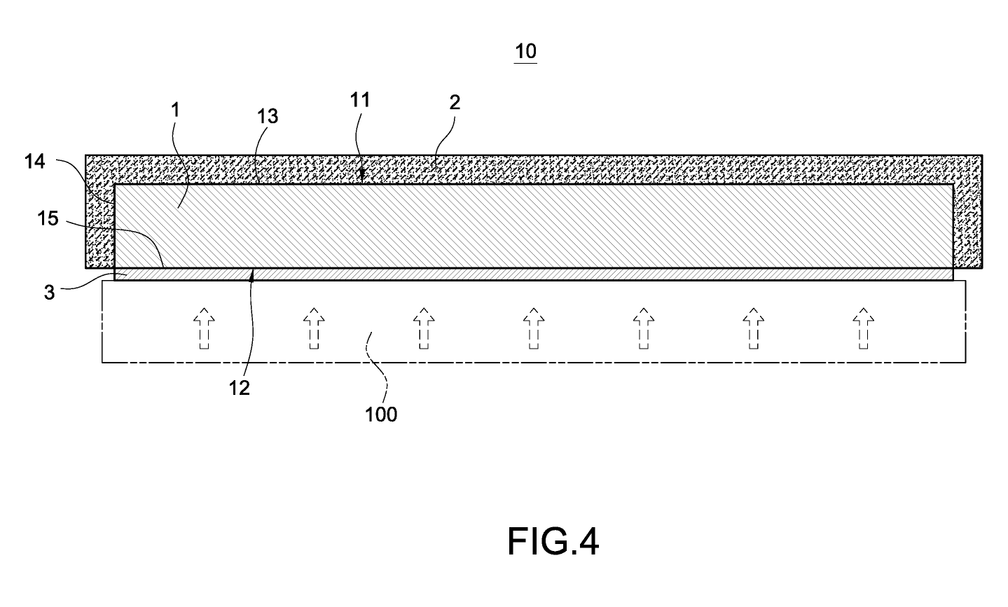

As shown in FIG. 3 to FIG. 4, the present invention provides another exemplary embodiment of a heat dissipation plate and a manufacturing method thereof. The second exemplary embodiment shown in FIG. 3 to FIG. 4 is generally identical with the first exemplary embodiment shown in FIG. 1 to FIG. 2. The difference between the second embodiment shown in FIG. 3 to FIG. 4 and the first embodiment shown in FIG. 1 to FIG. 2 relies in that the ceramic powder is disposed onto the heat dissipation surface 11 in order to form a ceramic powder layer 2, and the graphene layer 3 is disposed onto the heat absorbing surface 12.

The following provides further detailed description. As shown in steps d)˜f) in FIG. 3 and FIG. 4, a ceramic powder having the far infrared radiation capability is provided in step d), and a surface modification operation is performed on the ceramic powder. The purpose of the surface modification operation is to adjust the grain size, crystal phase or appearance of the ceramic powder in order to increase the fluidity of the ceramic powder. In step e), a substrate 1 is provided, and the substrate 1 includes a heat dissipation surface 1 and a heat absorbing surface 12. The ceramic powder is disposed onto the heat dissipation surface 11 via the spray method in order to form the ceramic powder layer 2. In step f), a graphene layer 3 is provided, and the graphene layer 3 is disposed onto the heat absorbing surface 12.

In addition, with regard to the surface modification operation adopted in this second exemplary embodiment, the spray method is generally identical with the spray method adopted in the first exemplary embodiment as shown in FIG. 1 to FIG. 2, and the difference from the first exemplary embodiment as shown in FIG. 1 to FIG. 3 relies in that a preliminary treatment procedure is further included before the spraying step. The preliminary treatment procedure is mainly to perform a step of cleaning action and surface roughenine treatment in order to increase the contact surface area of the ceramic powder particles in melted state or semi-melted state such that the spray process quality of the ceramic powder layer 2 can be increased.

Accordingly, the cleaning step is to remove the moisture, oxidation film or other grease and dirt etc. on the heat dissipation surface 11. A degreasing solvent is used to remove insoluble oil and grease as well as some attached dirt or debris etc. The cleaning effect generated by the degreasing solvent is able to clean off the aforementioned miscellaneous objects and significantly increase the bonding force between the disposing film and the workpiece with the film disposed thereon. Moreover, to achieve the physical bonding between the disposing film and the workpiece with the film disposed thereon, there is a need to increase the surface roughness of the heat dissipation surface 11 in such a way that when the aforementioned ceramic powder particles in melted state or semi-melted state impact onto the heat dissipation surface 11 along with the airflow, the particles are able to achieve a better retention due to the surface of relatively greater roughness (rough surface characteristic); consequently, the bonding strength between the surface of the ceramic powder layer 2 and the heat dissipation surface 11 can also be increased.

Please refer to FIG. 4. According to the second exemplary embodiment of the heat dissipation plate 10 obtained from the aforementioned manufacturing process, the ceramic powder layer 2 is stacked onto the heat dissipation surface 11, the graphene layer 3 is disposed onto the heat absorbing surface 12, and the graphene layer 3 is formed by a graphene material. Accordingly, when the heat dissipation plate 10 is attached onto a heat generating element 100 correspondingly, if the heat generating element 100 is a heat generating element of a transistor with the heat concentrated at one point, such graphene layer 3 is able to distribute such heat concentrated at one point outward and to rapidly conduct to the substrate. The heat is then transferred to the ceramic powder layer 2 from the substrate 1, and finally, the ceramic powder layer 2 then converts the thermal energy into the form of light quantum of electromagnetic radiation for dissipation to the external; consequently, the effect of fast heat dissipation can be achieved.

In addition, the following provides a further detailed description on the heat dissipation of the present invention. For a surface area of the graphene layer 3 of 3*3˜4*4 CM2, it is able to reduce approximately 1% of the temperature of a conventional heat sink; for a surface area of the graphene layer 3 of 5*5˜6*6 CM2, it is able to reduce approximately 2% of the temperature of a conventional heat sink; for a surface area of the graphene layer 3 of 7*7˜8*8 CM2, it is able to reduce approximately 3% of the temperature of a conventional heat sink; for a surface area of the graphene layer 3 above 9*9 CM2, it is able to reduce approximately 5% of the temperature of a conventional heat sink; therefore, the present invention is able to prevent the concentration of heat generated by the heat source occurred in conventional heat sinks and to overcome the ineffective heat dissipation of the temperature of the heat source in conventional heat sinks. Accordingly, the present invention is able to utilize the characteristics of high thermal conductivity of graphene to conduct the temperature of the heat source throughout the entire surface area of the heat dissipation plate in order to prevent the concentration of heat source. Therefore, a heat dissipation plate with a greater surface area is able to achieve a greater cooling effect. As a result, the heat dissipation plate 10 of the present invention is able to achieve the effects of uniform temperature and effective cooling.

In view of the above, the heat dissipation plate and the manufacturing method thereof of the present invention is able to achieve the expected objectives and overcome the drawbacks of known arts. In addition, the above describes the preferable and feasible exemplary embodiments of the present invention for illustrative purposes only, which shall not be treated as limitations of the scope of the present invention. Any equivalent changes and modifications made in accordance with the scope of the claims of the present invention shall be considered to be within the scope of the claim of the present invention.

What is claimed is:

1. A heat dissipation plate, comprising:
a substrate having a heat dissipation surface and a heat absorbing surface;
a ceramic powder layer stacked onto the heat dissipation surface, the ceramic powder layer formed by a ceramic powder having a far infrared radiation capability, and a thickness of the ceramic powder layer being smaller than 100 μm; and
a graphene layer stacked between the heat dissipation surface and the ceramic powder surface or disposed onto the heat absorbing surface; the graphene layer formed by a graphene material.

2. The heat dissipation plate according to claim 1, wherein the heat dissipation surface is formed on a top surface and a lateral circumferential surface of the substrate, and the heat absorbing surface is formed on a bottom surface of the substrate.

3. The heat dissipation plate according to claim 1, wherein the substrate is made of an aluminum or a copper material.

4. The heat dissipation plate according to claim 1, wherein the ceramic powder comprises clay, phyllite or tourmaline.

5. The heat dissipation plate according to claim 1, wherein the ceramic powder comprises potash feldspar, albite vanadic titanomagnetite, copper oxide or DK2001.

6. A manufacturing method for a heat dissipation plate, comprising the steps of:
a) providing a substrate and a graphene layer; the substrate having a heat dissipation surface; and disposing the graphene layer onto the heat dissipation surface;
b) providing a ceramic powder having a far infrared radiation capability in order to perform a surface modification operation on the ceramic powder; the surface modification operation being adopted to adjust a grain size, a crystal phase or an appearance of the ceramic powder in order to increase a fluidity of the ceramic powder; and
c) using a spray method to dispose the ceramic powder onto the graphene layer in order to form a ceramic powder layer.

7. The manufacturing method for a heat dissipation plate according to claim 6, wherein in step a), the substrate further comprises a heat absorbing surface, and the heat dissipation surface is formed on a top surface and a lateral circumferential surface of the substrate, and the heat absorbing surface is formed on a bottom surface of the substrate.

8. A manufacturing method for a heat dissipation plate, comprising the steps of:
d) providing a ceramic powder having a far infrared radiation capability to perform a surface modification operation on the ceramic powder; the surface modification operation being adopted to adjust a grain size, a crystal phase or an appearance of the ceramic powder in order to increase a fluidity of the ceramic powder;
e) providing a substrate, the substrate having a heat dissipation surface and a heat absorbing surface; using a spray method to dispose the ceramic powder onto the heat dissipation surface in order to form a ceramic powder layer; and
f) providing a graphene layer, and disposing the graphene layer onto the heat absorbing surface.

9. The manufacturing method for a heat dissipation plate according to claim 8, wherein the heat dissipation surface is formed on a top surface and a lateral circumferential surface of the substrate, and the heat absorbing surface is formed on a bottom surface of the substrate.
